(19) United States
(12) Patent Application Publication
(10) Pub. No.: US 2010/0139557 A1
(43) Pub. Date: Jun. 10, 2010

(54) REACTOR TO FORM SOLAR CELL ABSORBERS IN ROLL-TO-ROLL FASHION

(75) Inventor: Bulent M. Basol, Manhattan Beach, CA (US)

Correspondence Address: PILLSBURY WINTHROP SHAW PITTMAN LLP, P.O. BOX 10500, MCLEAN, VA, 22102, US

(73) Assignee: SoloPower, Inc., San Jose, CA (US)

(21) Appl. No.: 12/642,716

(22) Filed: Dec. 18, 2009

Related U.S. Application Data
(63) Continuation-in-part of application No. 12/345,389, filed on Dec. 29, 2008.
Application No. 12/345,389 is a continuation-in-part of application No. 12/334,420, filed on Dec. 12, 2008.
Application No. 12/334,420 is a continuation-in-part of application No. 12/027,169, filed on Feb. 6, 2008.
Application No. 12/027,169 is a continuation-in-part of application No. 11/938,679, filed on Nov. 12, 2007.
Application No. 11/938,679 is a continuation-in-part of application No. 11/549,590, filed on Oct. 13, 2006.
Application No. 11/549,590 is a continuation-in-part of application No. 12/177,007, filed on Jul. 21, 2008.
Application No. 12/177,007 is a continuation-in-part of application No. 12/027,169, filed on Feb. 6, 2008.
Application No. 12/345,389 is a continuation-in-part of application No. 11/938,679, filed on Nov. 12, 2007.
Application No. 11/938,679 is a continuation-in-part of application No. 11/549,590, filed on Oct. 13, 2006.
Application No. 11/549,590 is a continuation-in-part of application No. 11/938,679, filed on Nov. 12, 2007.
Application No. 11/938,679 is a continuation-in-part of application No. 11/549,590, filed on Oct. 13, 2006.
(60) Provisional application No. 61/141,208, filed on Dec. 29, 2008.

(51) Int. Cl. H01L 31/18

(52) U.S. Cl. 118/67; 257/E31.001

(57) ABSTRACT

A reactor to anneal a workpiece including a precursor material deposited over a flexible substrate is provided. The anneal process transforms the precursor material into a solar cell absorber when the workpiece is advanced through a process gap of the reactor. The process gap is defined by a peripheral wall including a top wall, a bottom wall and side walls. An exhaust opening located between the entrance and exit openings to remove gases from the continuous process gap. At least one roller having a rotational axis that is substantially transverse to the process direction and which has an outer roller surface disposed at least partially below the top wall of the continuous process gap forms a reduced gap between the outer surface of the roller and the bottom wall. The reduced gap is smaller than the process gap and the at least one roller is configured such that the workpiece travels through the reduced gap with the precursor material facing the at least one roller as the workpiece is moved between the entrance opening and the exit opening in a process direction.

### CROSS REFERENCE TO RELATED APPLICATIONS

This application claims priority to U.S. Provisional Patent Application Ser. No. 61/141,208 filed Dec. 29, 2008 entitled “Reactor to Form Solar Cell Absorbers in a Roll to Roll Fashion”, this application is a continuation-in-part of and claims priority to U.S. application Ser. No. 12/345,389, filed Dec. 29, 2008, entitled “METHOD AND APPARATUS TO FORM SOLAR CELL ABSORBER LAYERS WITH PLANAR SURFACE”; this application is a continuation-in-part of and claims priority to U.S. application Ser. No. 12/334,420 filed Dec. 12, 2008, entitled “REACTOR TO FORM SOLAR CELL ABSORBERS”, which is a continuation-in-part of U.S. patent application Ser. No. 12/027,169, filed Feb. 6, 2008, entitled “Reel-To-Reel Reaction of a Precursor Film to Form Solar Cell Absorber,” which is a continuation-in-part and claims priority to U.S. patent application Ser. No. 11/938,679, filed Nov. 12, 2007 entitled “Reel-To-Reel Reaction Of Precursor Film To Form A Solar Cell Absorber” and U.S. Utility Application 11/549,590 filed Oct. 13, 2006 entitled “Method and Apparatus For Converting Precursor Layers Into Photovoltaic Absorbers”; this application is a continuation-in-part of and claims priority to U.S. application Ser. No. 12/177,007 filed Jul. 21, 2008, entitled “METHOD AND APPARATUS TO FORM THIN LAYERS OF PHOTOVOLTAIC ABSORBERS”; this application is a continuation-in-part of and claims priority to U.S. application Ser. No. 12/027,169 filed Feb. 6, 2008, entitled “REEL-TO-REEL REACTION OF A PRECURSOR FILM TO FORM SOLAR CELL ABSORBER”, which is a CIP of U.S. patent application Ser. No. 11/938,679, filed Nov. 12, 2007, entitled “Reel to Reel Reaction of Precursor Film to Form Solar Cell Absorber”, which is a CIP of U.S. patent application Ser. No. 11/549,590 filed Oct. 13, 2006, entitled “Method and Apparatus for Converting Precursor Layers into Photovoltaic Absorbers ”; this application is a continuation-in-part of and claims priority to U.S. application Ser. No. 11/938,679 filed Nov. 12, 2007, entitled “REEL TO REEL REACTION OF PRECURSOR FILM TO FORM SOLAR CELL ABSORBER”, which is a CIP of U.S. patent application Ser. No. 11/549,590, filed Oct. 13, 2006, entitled “Method and Apparatus for converting Precursor Layers into Photovoltaic Absorbers ”; and this application is a continuation-in-part of and claims priority to U.S. application Ser. No. 11/549,590 filed Oct. 13, 2006, entitled “METHOD AND APPARATUS FOR CONVERTING PRECURSOR LAYERS INTO PHOTOVOLTAIC ABSORBERS”; all of which are expressly incorporated herein by reference in their entirety.

### FIELD OF THE INVENTIONS

The present inventions relate to method and apparatus for preparing thin films of semiconductor films for radiation detector and photovoltaic applications using a roll-to-roll process and reactor tool.

### BACKGROUND

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIA VIA compound semiconductors including some of the Group IB (Cu, Ag, Au), Group IIIA (B, Al, Ga, In, Tl) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ (S_{y}Se_{1-y})ₖ, where 0≦x≦1, 0≦y≦1 and k is approximately 2, have already been employed in solar cell structures that yielded conversion efficiencies approaching 20%. Absorbers containing Group IIIA element Al and/or Group VIA element Te also showed promise. Therefore, in summary, compounds containing: i) Cu from Group IB, ii) at least one of In, Ga, and Al from Group IIIA, and iii) at least one of S, Se, and Te from Group VIA, are of great interest for solar cell applications.

The structure of a conventional Group IBIIIA VIA compound photovoltaic cell such as a Cu(In,Ga,Al)(S,Se,Te)₂ thin film solar cell is shown in FIG. 1. The device 10 is fabricated on a substrate 11, such as a sheet of glass, a sheet of metal, an insulating foil or web, or a conductive foil or web. The absorber film 12, which includes a material in the family of

Cu(In,Ga,Al)(S,Se,Te)₂, is grown over a conductive layer 13, which is previously deposited on the substrate 11 and which acts as the electrical contact to the device. The substrate 11 and the conductive layer 13 form a base 20. Various conductive layers including Mo, Ta, W, Ti, and stainless steel etc. have been used in the solar cell structure of FIG. 1. If the substrate itself is a properly selected conductive material, it is possible not to use a conductive layer 13, since the substrate 11 may then be used as the ohmic contact to the device. After the absorber film 12 is grown, a transparent layer 14 such as a CdS, ZnO or CdS/ZnO stack is formed on the absorber film. Radiation 15 enters the device through the transparent layer 14. Metallic grids (not shown) may also be deposited over the transparent layer 14 to reduce the effective series resistance of the device. The preferred electrical type of the absorber film 12 is p-type, and the preferred electrical type of the transparent layer 14 is n-type. However, an n-type absorber and a p-type window layer can also be utilized. The preferred device structure of FIG. 1 is called a “substrate-type” structure. A “superstrate-type” structure can also be constructed by depositing a transparent conductive layer on a transparent superstrate such as glass or transparent polymeric foil, and then depositing the Cu(In,Ga,Al)(S,Se,Te)₂ absorber film, and finally forming an ohmic contact to the device by a conductive layer. In this superstrate structure light enters the device from the transparent superstrate side. A variety of materials, deposited by a variety of methods, can be used to provide the various layers of the device shown in FIG. 1.

In a thin film solar cell employing a Group IBIIIA VIA compound absorber, the cell efficiency is a strong function of the molar ratio of IB/IIIA. If there are more than one Group IIIA materials in the composition, the relative amounts or molar ratios of these IIIA elements also affect the properties. For a Cu(In,Ga)(S,Se)₂ absorber layer, for example, the efficiency of the device is a function of the molar ratio of Cu/(In+Ga). Furthermore, some of the important parameters of the cell, such as its open circuit voltage, short circuit current and fill factor vary with the molar ratio of the IIIA elements, i.e. the Ga/(Ga+In) molar ratio. In general, for good device performance Cu/(In+Ga) molar ratio is kept at around or below 1.0. As the Ga/(Ga+In) molar ratio increases, on the other hand, the optical bandgap of the absorber layer increases and therefore the open circuit voltage of the solar cell increases while the short circuit current typically may decrease. It is important for a thin film deposition process to have the capability of controlling both the molar ratio of IB/IIIA, and the molar ratios of the Group IIIA components in the composition. It should be noted that although the chemical formula is often written as Cu(In,Ga)(S,Se)₂, a more accurate formula for the compound is Cu(In,Ga)(S,Se)ₖ, where k is typically close to 2 but may not be exactly 2. For simplicity we will continue to use the value of k as 2. It should be further noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1.

One technique for growing Cu(In,Ga)(S,Se)₂ type compound thin films for solar cell applications is a two-stage process where metallic components of the Cu(In,Ga)(S,Se)₂ material are first deposited onto a substrate, and then reacted with S and/or Se in a high temperature annealing process. For example, for CuInSe₂ growth, thin layers of Cu and In are first deposited on a substrate and then this stacked precursor layer is reacted with Se at elevated temperature. If the reaction atmosphere also contains sulfur, then a CuIn(S,Se)₂ layer can be grown. Addition of Ga in the precursor layer, i.e. use of a Cu/In/Ga stacked film precursor, allows the growth of a Cu(In,Ga)(S,Se)₂ absorber.

Two-stage process approach may also employ stacked layers including Group VIA materials. For example, a Cu(In,Ga)Se₂ film may be obtained by depositing In—Ga—Se and Cu—Se layers in an In—Ga—Se/Cu—Se stack and reacting them in presence of Se. Similarly, stacks including Group VIA materials and metallic components may also be used. Stacks having Group VIA materials include, but are not limited to In—Ga—Se/Cu stack, Cu/In/Ga/Se stack, Cu/Se/In/Ga/Se stack, etc. Sputtering and evaporation techniques can be used to deposit the layers containing the Group IB and Group IIIA components of the precursor stacks. In the case of CuInSe₂ growth, for example, Cu and In layers is sequentially sputter-deposited on a substrate and then the stacked film is heated in the presence of gas containing Se at elevated temperature for times typically longer than about 30 minutes, as described in U.S. Pat. No. 4,798,660. U.S. Pat. No. 6,048,442 discloses a method having sputter-depositing a stacked precursor film having a Cu—Ga alloy layer and an In layer to form a Cu—Ga/In stack on a metallic back electrode layer and then reacting this precursor stack film with one of Se and S to form the absorber layer. U.S. Pat. No. 6,092,669 describes sputtering-based equipment for producing such precursor layers.

Selenization and/or sulfidation or sulfurization of precursor layers including metallic components may be carried out in various forms of Group VIA material(s). One approach involves using gases such as H₂Se, H₂S or their mixtures to react, either simultaneously or consecutively, with the precursor including Cu, In and/or Ga. This way a Cu(In,Ga)(S,Se)₂ film may be formed after annealing and reacting at elevated temperatures. It is possible to increase the reaction rate or reactivity by striking plasma in the reactive gas during the process of compound formation. Se vapors or S vapors from elemental sources may also be used for selenization and sulfidation. Alternately, as described before, Se and/or S may be deposited over the precursor layer including Cu, In and/or Ga and the stacked structure can be annealed at elevated temperatures to initiate reaction between the metallic elements or components and the Group VIA material(s) to form the Cu(In,Ga)(S,Se)₂ compound.

Reaction step in a two-stage process is typically carried out in batch furnaces. In this approach, a number of pre-cut substrates, typically glass substrates, with precursor layers deposited on them are placed into a batch furnace and reaction is carried out for periods that may range from 15 minutes to several hours. Temperature of the batch furnace is typically raised to the reaction temperature, which may be in the range of 400-600° C., after loading the substrates. The ramp rate for this temperature rise is normally lower than 5° C./sec, typically less than 1° C./sec. This slow heating process works for selenizing metallic precursors (such as precursor layers containing only Cu, In and/or Ga) using gaseous Se sources such as H₂Se or organometallic Se sources. For precursors containing solid Se, however, slow ramp rate reportedly causes Se de-wetting and morphological problems. For example, reacting a precursor layer with a structure of base/Cu/In/Se by placing it in a batch furnace with a low temperature rise rate (such as 1° C./sec) is reported to yield films that are powdery and non-uniform. Such defective films would not yield high efficiency solar cells.

One prior art reaction method described in U.S. Pat. No. 5,578,503 utilizes a rapid thermal annealing (RTP) approach to react the precursor layers in, a batch manner, one substrate at a time. Such RTP approaches are also disclosed in various publications (see, for example, Mooney et al., Solar Cells, vol: 30, p: 69, 1991, Gabor et al., AIP Conf. Proc. #268, PV Advanced Research & Development Project, p: 236, 1992, and Kerr et al., IEEE Photovoltaics Specialist Conf., p: 676, 2002). In the prior art RTP reactor design the temperature of the substrate with the precursor layer is raised to the reaction temperature at a high rate, typically at 10° C./sec or higher. It is believed that such high temperature rise through the melting point of Se (220° C.) avoids the problem of de-wetting and thus yields films with good morphology.

Design of the reaction chamber to carry out selenization/sulfidation processes is critical for the quality of the resulting compound film, the efficiency of the solar cells, throughput, material utilization and cost of the process. Furthermore, it is important to carry out this selenization/sulfidation process in an environment that is substantially free of oxygen because presence of oxygen would promote formation of Cu, In, and Ga oxide formation, lowering the photovoltaic quality of the resulting solar cell absorber. In prior art batch reaction approaches, reaction processes that involve reaction of a precursor with more than one Group VIA material, was typically carried out in a serial mode. For example, for CIGSS film formation, a precursor layer in the form of a Cu—Gal/In stack is first selenized in a furnace or reactor using H₂Se gas as the Se source. After reaction at about 400-450° C., a CIGS film is obtained. The furnace is then evacuated and its temperature is raised to over 500° C. At the same time H₂S gas is introduced into the reactor. The CIGS film formed during the first reaction step is now further reacted with S to form a CIGSS layer which is used as a solar cell absorber. It can be appreciated that such batch processes are time consuming and involve several pumping/purging/reactive gas replacement steps.

### SUMMARY

The present inventions provide a method and integrated tool to form solar cell absorber layers on continuous flexible substrates. A roll-to-roll rapid thermal processing reactor tool including multiple process gap sections is used to react a precursor layer on a continuous flexible workpiece for CIGS(S) type absorber formation. Rollers are used in the process gap sections of the reactor to avoid defects and also to improve materials utilization.

### BRIEF DESCRIPTION OF THE DRAWINGS

FIG. 1 is a cross-sectional view of a solar cell employing a Group IBIIIA VIA absorber layer;

FIG. 2A is a schematic side view of an embodiment of a reactor according to a preferred embodiment;

FIG. 2B is a schematic cross sectional view of the reactor shown in FIG. 2A taken along the line 2B-2B; and

FIG. 2C is a schematic detail view of a portion of the reactor including an isolation roller according to a preferred embodiment.

### DETAILED DESCRIPTION

Reaction of precursors, comprising Group IB material(s), Group IIIA material(s) and optionally Group VIA material(s) or components, with Group VIA material(s) may be achieved in various ways. These techniques involve heating the precursor layer to a temperature range of 350-600° C., preferably to a range of 400-575° C., in the presence of at least one of Se, S, and Te provided by sources such as; i) solid Se, S or Te sources directly deposited on the precursor, and ii) H₂Se gas, H₂S gas, H₂Te gas, Se vapors, S vapors, Te vapors etc. for periods ranging from 1 minute to several hours. If reaction with more than one Group VIA material is involved such reactions may be carried out in a single or serial manner. In other words, if a precursor is reacted with Se and S, the reaction may be carried out by: i) reacting the precursor with Se first and then with S, ii) reacting the precursor with S first and then with Se, iii) reacting the precursor with Se and S simultaneously, or iv) mixing any of the methods i), ii) and iii). The Se, S, Te vapors may also be generated by heating solid sources of these materials away from the precursor. Hydride gases such as H₂Se and H₂S may be bottled gases. Such hydride gases and short-lifetime gases such as H₂Te may also be generated in-situ, for example by electrolysis in aqueous acidic solutions of cathodes comprising S, Se and/or Te, and then provided to the reactors. Electrochemical methods to generate these hydride gases are suited for in-situ generation.

As stated above, precursor layers may be exposed to more than one Group VIA materials either simultaneously or sequentially. For example, a precursor layer comprising Cu, In, Ga, and Se may be annealed in presence of S to form Cu(In,Ga)(S,Se)₂. The precursor layer in this case may be a stack comprising a metallic layer containing Cu, Ga and In, and a Se layer that is deposited over the metallic layer. Alternately, Se nano-particles may be dispersed throughout the metallic layer containing Cu, In and Ga. It is also possible that the precursor layer comprises Cu, In, Ga and S, and during the reaction this layer is annealed in presence of Se to form a Cu(In,Ga)(S,Se)₂.

Some of the preferred embodiments of forming a Cu(In,Ga)(S,Se)₂ compound layer may be summarized as follows: i) depositing a layer of Se on a metallic precursor comprising Cu, In and Ga forming a structure and reacting the structure in gaseous S source at elevated temperature, ii) depositing a mixed layer of S and Se or a layer of S and a layer of Se on a metallic precursor comprising Cu, In and Ga forming a structure, and reacting the structure at elevated temperature in either a gaseous atmosphere free from S or Se, or in a gaseous atmosphere comprising at least one of S and Se, iii) depositing a layer of S on a metallic precursor comprising Cu, In and Ga forming a structure and reacting the structure in gaseous Se source at elevated temperature, iv) depositing a layer of Se on a metallic precursor comprising Cu, In and Ga forming a structure, and reacting the structure at elevated temperature to form a Cu(In,Ga)Se₂ layer and/or a mixed phase layer comprising selenides of Cu, In, and Ga and then reacting the Cu(In,Ga)Se₂ layer and/or the mixed phase layer with a gaseous source of S, liquid source of S or a solid source of S such as a layer of S, v) depositing a layer of S on a metallic precursor comprising Cu, In and Ga forming a structure, and reacting the structure at elevated temperature to form a Cu(In,Ga)S₂ layer and/or a mixed phase layer comprising sulfides of Cu, In, and Ga, and then reacting the Cu(In,Ga)S₂ layer and/or the mixed phase layer with a gaseous source of Se, liquid source of Se or a solid source of Se such as a layer of Se.

It should be noted that Group VIA materials are corrosive. Therefore, materials for all parts of the reactors or chambers that are exposed to Group VIA materials or material vapors at elevated temperatures should be properly selected. These parts should be made of or should be coated by substantially inert materials such as ceramics, e.g. alumina, tantalum oxide, titanic, zirconia etc., glass, quartz, stainless steel, graphite, refractory metals such as Ta, refractory metal nitrides and/or carbides such as Ta-nitride and/or carbide, Ti-nitride and/ or carbide, W-nitride and/or carbide, other nitrides and/or carbides such as Si-nitride and/or carbide, etc.

Reaction of precursor layers comprising Cu, In, Ga and optionally at least one Group VIA material may be carried out in a reactor that applies a process temperature to the precursor layer at a low rate. Alternately, rapid thermal processing (RTP) may be used where the temperature of the precursor is raised to the high reaction temperature at rates that are at least about 10° C./sec. Group VIA material, if included in the precursor layer, may be obtained by evaporation, sputtering, or electroplating. Alternately inks comprising Group VIA nano particles may be prepared and these inks may be deposited to form a Group VIA material layer within the precursor layer. Other liquids or solutions such as organometallic solutions comprising at least one Group VIA material may also be used. Dipping into melt or ink, spraying melt or ink, doctor-blading or ink writing techniques may be employed to deposit such layers.

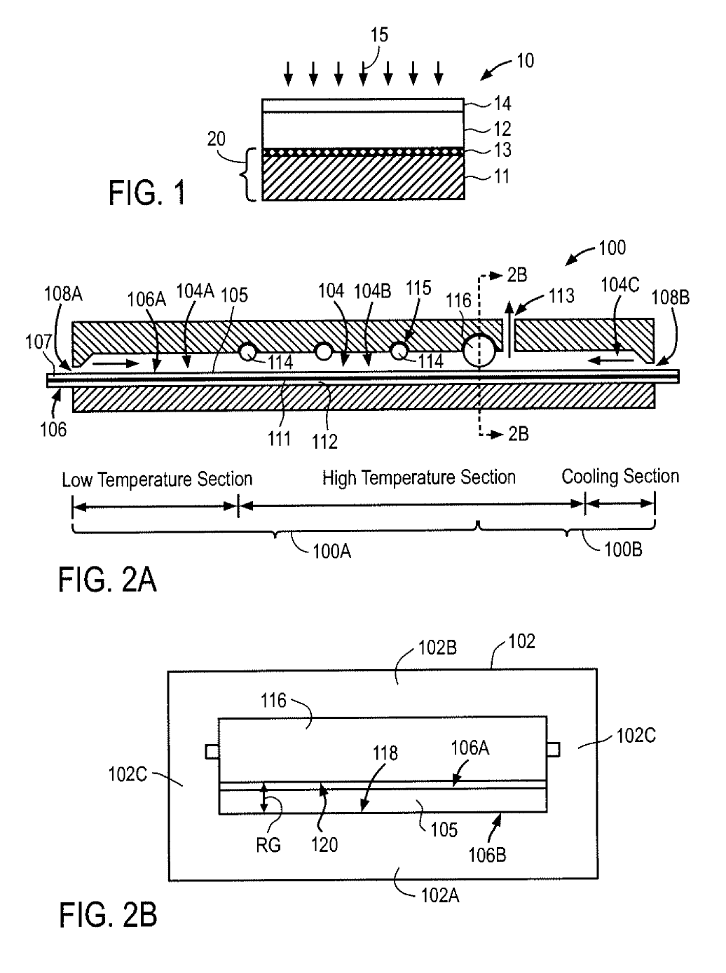

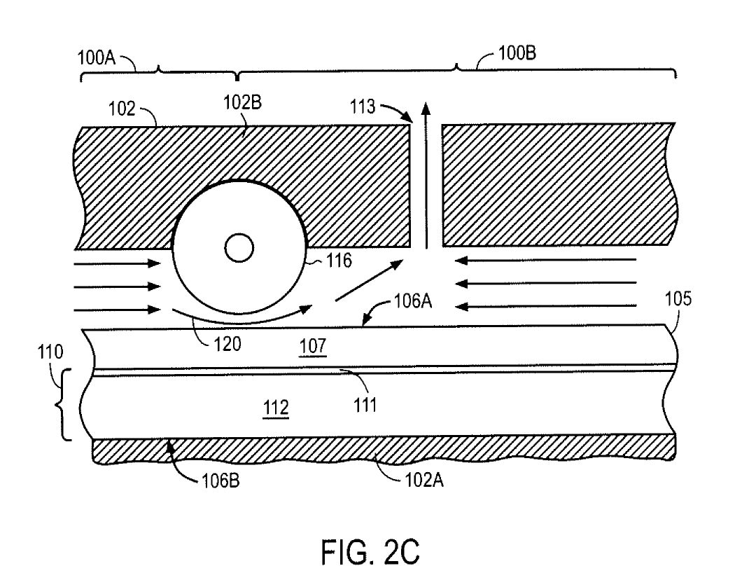

A reel-to-reel apparatus 100 or roll to roll RTP reactor to carry out reaction of a precursor layer to form a Group IBIIIA VIA compound film is shown in FIG. 2A. It should be noted that the precursor layer to be reacted in this reactor may comprise at least one Group 18 material and at least one Group IIIA material. For example the precursor layer may be a stack of Cu/In/Ga, Cu—Ga/In, Cu—In/Ga, Cu/In—Ga, Cu—Ga/Cu—In, Cu—Ga/Cu—In/Ga, Cu/Cu—In/Ga, or Cu—Ga/In/In—Ga, Cu—In—Ga, etc., where the order of various material layers within the stack may be changed. Here Cu—Ga, Cu—In, In—Ga, Cu—In—Ga mean alloys or mixtures of Cu and Ga, alloys or mixtures of Cu and In, alloys or mixtures of In and Ga, and alloys or mixtures of Cu, In and Ga respectively. Alternatively, the precursor layer may also include at least one Group VIA material. There are many examples of such precursor layers, Some of these are Cu/In/Ga/Group VIA material stack, Cu-Group VIA material/In/Ga stack, In-Group VIA material/Cu-Group VIA material stack, or Ga-Group VIA material/Cu/In stack, where Cu-Group VIA material includes alloys, mixtures or compounds of Cu and a Group VIA material (such as Cu-selenides, Cu sulfides, etc.), In-Group VIA material includes alloys, mixtures or compounds of In and a Group VIA material (such as In-selenides, In sulfides, etc.), and Ga-Group VIA material includes alloys, mixtures or compounds of Ga and a Group VIA material (such as Ga-selenides, Ga sulfides, etc.). These precursors are deposited on a base 20 comprising a substrate 11, which may additionally comprise a conductive layer 13 as shown in FIG. 1. Other types of precursors that may be processed using the method and apparatus of the embodiments described herein include Group IBIIIA VIA material layers that may be formed on a base using low temperature approaches such as compound electroplating, electroless plating, sputtering from compound targets, ink deposition using Group IBIIIA VIA nano-particle based inks, spraying metallic nanoparticles comprising Cu, In, Ga and optionally Se, etc. These material layers are then annealed in the apparatus or reactors at temperatures in the 350-600° C. range to improve their crystalline quality, composition and density.

Annealing and/or reaction steps may be carried out in the reactors of the present embodiments at substantially the atmospheric pressure, at a pressure lower than the atmospheric pressure or at a pressure higher than the atmospheric pressure. Lower pressures in reactors may be achieved through use of vacuum pumps. In one embodiment, a precursor layer may be reacted within a system that is used for treating or reacting a precursor layer to transform the precursor layer into a high quality solar cell absorber such as a high quality Group IBIIIA VIA film in a continuous reel-to-reel manner. In one embodiment, the system includes a reactor to react a precursor layer formed on a front surface of a base, which may be a continuous flexible base. Roll-to-roll or reel-to-reel processing increases throughput and minimizes substrate handling; therefore, it is a preferred method for large scale manufacturing.

FIGS. 2A and 2B show in side view and a cross sectional view, a continuous reactor 100 including peripheral reactor walls 102 and a process gap 104 defined by the peripheral reactor walls 102. A continuous workpiece 105 having a front surface 106A and a back surface 106B is advanced through the process gap and over a bottom wall 102A of the peripheral reactor walls 102 while a top layer 107 of the continuous workpiece 105 is reacted and transformed. The top layer 107 may be a precursor layer comprising Cu, at least one Group IIIA material and optionally at least one Group VIA material such as Se. The continuous workpice 105 enters the process gap 104 through an entrance opening 108A; it is advanced through the process gap while the top layer 107 is reacted; and leaves the process gap 104 through an exit opening 108B of the process gap 104. The top layer 107 of the continuous workpiece is formed over a base layer 110 including a contact layer 111 and a flexible substrate 112, thereby the top surface 106A of the workpiece is the top surface of the top layer 107 (see FIG. 2C). Before being advanced into the process gap, the top layer 107 includes a precursor material comprising, for example, Cu, In, Ga and optionally Se, i.e., the top layer is a precursor layer before reaction in the continuous reactor 100. As the workpiece is advanced through the process gap 104 and reacted, the precursor material is converted into a Group IBIIIA VIA absorber material with the applied heat and optionally gaseous species comprising Group VIA materials. Therefore, the top layer 107 of the continuous workpiece 105 exiting the process gap 104 comprises the absorber material, i.e. the top layer 107 is fully converted into the absorber material. The process gap 104 is heated by the heating elements placed inside or outside of the peripheral walls 102, peripheral walls comprising bottom 102A, top 102B and side 102C walls. The heating elements heat the peripheral walls 102 which in turn heat the process gap and the continuous workpiece 105 traveling through the process gap 104. There may also be cooling coils to cool selected regions of the peripheral walls. In some designs there may be an insert within the cavity formed by the peripheral walls. In this case, the process gap is within the peripheral walls of the insert. Details of the exemplary reactors can be found in the following patent application of the same assignee: U.S. patent application Ser. No. 11/549,590 filed on May 17, 2007 entitled Method and Apparatus for converting precursor layers into photovoltaic absorbers, and U.S. patent application Ser. No. 12/334,420 filed on Dec. 12, 2008 entitled Reactor to Form Solar Cell Absorbers, which are incorporated herein by reference in their entirety. In general, the process gap 104 includes a temperature profile of at least three sections to fully convert the precursor material layer on the base 110 into the absorber layer. Approximate locations of the exemplary sections along the process gap 104 can be seen along a reference line positioned below the continuous reactor 100.

Accordingly, a low temperature section 104A is located adjacent the entrance opening 108A; a cooling section 104C is located adjacent the exit opening of the process gap 104; and a high temperature section 104B is located between the low temperature section and the cooling section. Furthermore, the continuous reactor 100 comprises a first reactor region 100A and a second reactor region 100B. The temperature in the low temperature section, high temperature section and cooling section may be in the range of 20-350° C., 400-600° C., and below 100° C., respectively. Unprocessed sections of the continuous workpiece 105, entering the process gap 104, may be unwrapped from a supply spool (not shown) and the processed portions, exiting the process gap, are taken up and wound around a receiving spool (not shown). During the process, inert gases such as nitrogen may be flowed into the process gap 104 through the entrance opening 108A and exit opening 108B to form a diffusion barrier against volatile species such as Group VIA material containing vapors within the process gap 104 to escape through the entrance opening 108A and exit opening 108B. Process gases may also be provided to the process gap 104 by at least one gas inlet connected to the process gap 104. Details of the exemplary reactors for the formation of CIGS(S) type absorber layers on continuous workpieces can be found in U.S. patent application Ser. Nos. 12/345,389, 12/334,420, 12/177,007, 12/027,169, 11/938,679, and 11/549,590, each of which are mentioned hereinbefore. Used gases and Group VIA containing vapors are removed from the process gap 104 through an exhaust opening 113 placed closer to the exit opening 108B. It should be noted that other exhausts or exhaust openings located at different locations between the entrance opening 108A and exit opening 108B may also be utilized. Exhausts are preferably heated to temperatures above 250° C., preferably above 300° C., to avoid any condensation of Se and/or S species at these locations. Also cool exhaust lines would form a sink for Group VIA element vapors causing poor materials utilization within the reactor.

In the novel reactor designs of the embodiments herein it is possible to react precursors with more than one species in a serial manner. In this case, it is necessary to separate the more than one gaseous species from each other within the process gap 104. Another concern in the reactor is enhancement of materials utilization. Reaction of precursor layers comprising Cu, In, Ga, with Se or S, for example, typically consume much more Se or S than the amount necessary to form the CIGS(S) compound. This is because Group VIA materials such as Se and S are relatively volatile materials and they are in vapor form at reaction temperatures which is typically in the range of 400-600° C. Hydrides (H₂Se, H₂S) containing Se and S are gases even at room temperature. Therefore, during reaction with the precursor layer, these volatile species need to be contained as much as possible within as small a cavity as possible. When these volatile species arrive on the surface of the precursor layer they react with it and form non-volatile selenide and sulfide compounds. Therefore, increasing the residence time of the gaseous Se and S species over the precursor layer and increasing their rate of impingement onto the precursor layer surface are necessary to increase their utilization, i.e. their inclusion into the selenide and/or sulfide compounds that are forming as a result of reaction. Any volatile Se and/or S species that do not find a chance to react with the precursor layer are directed to outside the process gap through the exhaust opening. Exhausted Se and/or S constitute un-utilized material, i.e. a materials loss. Such loss increases the cost of the overall reaction process. increasing Group VIA materials utilization requires the gap 104 to be as narrow as possible. Very narrow process gaps, such as a gap with a height of 2-3 mm, on the other hand, may cause scratching of the precursor layer during or after reaction if the precursor layer touches the top wall 102B of the peripheral walls 102 as it moves through the process gap.

In the design of the embodiments herein, in order to avoid any physical contact between the top layer 107 of the continuous workpiece 105 and the top wall 102A of the peripheral walls 102 when the continuous workpiece 105 is advanced through the process gap 104, one or more movable buffer members 114 are placed adjacent the top wall 102B to form reduced gap sections in the process gap, preferably in the high temperature section 104B. In this embodiment the movable buffer members 114 may be protection rollers that rotate and prevent any surface damage if the top layer 107 touches them. The protection rollers 114 are provided to prevent any scratching of the top layer 107 if the continuous workpiece bows up against the top wall 102B because of the thermal expansion caused by the entry of the continuous workpiece into the high temperature section 104B from the low temperature section 104A. This is a unique problem associated with continuous metallic webs or workpieces where a first portion of the web is kept at a low temperature, for example at room temperature, while the temperature of a second portion which is adjacent to the first portion is raised to an elevated temperature, such as to a temperature range of 250-600° C. In such a situation the second portion expands while the first portion stays the same. This causes the web to deform to absorb the dimensional differential (which is a width differential in the case of a thin and wide foil) between the first and second portions. Because of the low aspect ratio of the process gap 104, the vertical distance between the top wall 102B and ₜhe front surface 106A of the continuous workpiece may be about 2-10 mm. Without the protection rollers 114, in the high temperature section 102B, the continuous workpiece may bow upwardly and the top layer 107 may touch the top wall 102B, resulting in damage to the absorber layer that is forming. In order to prevent this contact between the workpiece and top wall in such narrow process gaps, increasing the height of the gap to the 10-25 mm range may be considered as one of the solutions. However, as explained before, narrow gaps have attractive benefits in terms of increased materials utilization and efficient use of generated heat. Use of protection rollers results in further reduction of the height of the process gap, which further increases the efficiency of the reaction process. In one embodiment, the length of the protection rollers 114 may be substantially equal to the width of the process gap 104 and the protection rollers may be placed within the semi circular cavities 115 extending along the width of the top wall 102B. The length of the rollers may be in the range of 20-200 cm or longer depending on the width of the process gap 104. The diameter of the rollers may be in the range of 2-20 mm, preferably in the range of 3-6 mm. They may be constructed using inert materials such as ceramics, quarts and graphite, or they may have inert coatings on their outer surfaces. The rollers may be driven (rotated by a motor) at a speed such that their surface linear velocity is about the same as the linear velocity of the moving workpiece. Alternately, the rollers may be idle rollers that rotate only when touched by the workpiece. Although in FIG. 2A there are only three of the protection rollers 114 shown, there may be more or less rollers 114 in the various locations along the high temperature section 104B within the first reactor section 100A and second reactor section 100B.

The principles of using the movable buffer members described in the embodiments herein to avoid physical damage to the top layer 107 of the continuous workpiece 105 may be advantageously used for further narrowing the process gap 104 at a selected location without concern about damage to the top layer 107 of the continuous workpiece 105. Referring to FIG. 2A, a movable isolation and buffer member 116 located close to the exhaust opening 113 effectively reduces the distance between the top wall 102A and the front surface 106A of the continuous workpiece and divides the reactor into two segments; the first reactor segment 100A and the second reactor segment 100B. Narrowing the process gap at this location before the exhaust opening 113 advantageously allows efficient use of two different vapor species in the two different segments (the first reactor segment 100A and the second reactor segment 100B) of the process gap. Referring to FIGS. 2A and 2B, in this embodiment, the movable isolation and buffer member 116 may be an isolation roller that is dimensioned to form a reduced gap RG between a surface 118 of the bottom wall 102A and a lower end 120 of the isolation roller 116. FIG. 2B is a front cross sectional view of the continuous reactor 100 showing an exemplary isolation roller 116 within the process gap defined by the peripheral walls 102 comprising the bottom wall 102A, the top wall 102B and the side walls 102C. At the reduced gap RG the vertical distance between the front surface 106A and the lower end 120 of the isolation roller may be very small, e.g. in the range of 1-2 mm. As shown in FIG. 2B, the isolation roller 116 extends along the width of the process gap 104 and is movably attached to the side walls 102C so that if the front surface 106A of the continuous workpiece touches it, the isolation roller 116 rotates and prevents any excessive friction and damage on the front surface 106A. As shown in FIGS. 2A and 2B, the isolation roller 116 may be movably placed into a semi circular cavity formed in the top wall 102B of the process gap 104.

The isolation function of the isolation roller 116 may be seen in a partial view of the continuous reactor 100 shown in FIG. 2C. The isolation roller 116 blocks the majority of the gas flow from the portion of the process gap within the first reactor segment 100A into the portion of the process gap within the second reactor segment 100B. This serves two purposes; i) reduced gap under the isolation roller 116 increases the velocity of the gas under the isolation roller 116 (shown by arrow 120), establishing an efficient diffusion barrier against any appreciable transfer of gaseous species from the portion of the process gap within the second reactor segment 100B into the portion of the process gap within the first reactor segment 100A, ii) effective diffusion barrier between the two reactor segments allows reduction of the gas flow from the portion of the process gap within the first reactor segment 100A towards the exhaust opening 113, increasing the residence time of any Group VIA volatile species in the portion of the process gap within the first reactor segment 100A. As discussed before, increased residence time increases materials utilization. We will now describe an example for the growth of a CIGS absorber layer on a flexible base.

A workpiece comprising a precursor layer deposited on a flexible base may be used in the reactor of FIG. 2A. The exemplary precursor layer comprises metallic Cu, In and Ga species as well as elemental Se. A portion of the workpiece travels from the entry 108A to exit 108B and reaction within the process gap forms the CIGS layer on the base. Inert gases such as nitrogen are flown into the process gap from the entry 108A and exit 108B openings. The flow from the entry opening may be 1-10% of the flow from the exit opening. For example, the flow from the exit opening may be in the range of 0.5-10 liters/minute, whereas the flow from the entry opening may be as small as 0.005 liters/minute. As described before, existence of the isolation roller 116 allows the use of such low flows within the first reactor segment 100A. As the portion of the workpiece is moved from left to right within the first reactor segment 100A, the Cu, In, Ga and Se in the precursor layer starts reacting with each other. Some of the Se evaporates and fills the portion of the process gap within the first reactor segment 100A since it is volatile. However, the small gas flow within the first reactor segment 100A keeps the evaporated Se vapors within the process gap portion between the entry 108A and the isolation roller 116 for a long period of time so that they can be reacted with precursor layer in other portions of the workpiece being fed through the entry 108A. Once the reacted portion of the workpiece enters the second reactor segment 100B, it may be treated with the inert gas present in the portion of the process gap within the second reactor segment 100B until it exits the reactor through the exit 108B. Alternately, a S source such as H₂S may be fed into the portion of the process gap within the second reactor segment 100B and further reaction of the CIGS film (formed in the first reactor segment 100A) with S may be achieved to form a CIGSS compound layer. Presence of the isolation roller 116 does not allow substantial diffusion of S species from the portion of the process gap within the second reactor segment 100B into the portion of the process gap within the first reactor region 100A.

It should be noted that more isolation rollers may be placed in various other locations within the process gap 104 to enhance material utilization and/or improve isolation between various reactor segments or regions. For example, an additional isolation roller (not shown) may be placed to the right of the exhaust opening 113 to improve materials utilization of gaseous species in the second reactor segment 100B between the exit opening 108B and the additional isolation roller. The additional isolation roller also substantially prevents the gaseous species coming from the first reactor segment 100A towards the exhaust opening 113, from entering the second reactor segment 100B between the exit opening 108B and the additional isolation roller. This way two different reactions may be carried out in the two segments of the reactor very efficiently and avoiding damage to the solar cell absorber layer surface. Isolation rollers may even be used at the entry and exit openings to reduce the inert or process gas flows through these openings while preventing the volatile species from coming out of the reactor through these openings. Also it is possible to place rollers into the bottom peripheral walls to reduce damage to the back side of the workpiece. Planarization rollers may also be used in a low temperature segment of the reactor as described in U.S. patent application Ser. No. 12/345,389, which application is expressly incorporated by reference herein. Details of the exemplary reactors including rollers can be found in the following patent application of the assignee of the present application, which is incorporated herein by reference in its entirety: U.S. application Ser. No. 12/334,420 filed on Dec. 12, 2008 entitled Reactor to Form Solar Cell Absorbers.

Although the present invention is described with respect to certain preferred embodiments, modifications thereto will be apparent to those skilled in the art.

I claim:

1. A reactor used to anneal a continuous workpiece including a precursor material deposited over a flexible substrate as the continuous workpiece is advanced through the reactor in a process direction, wherein the anneal process transforms the precursor material into a solar cell absorber, the reactor comprising:
a continuous process gap defined by a peripheral wall including a top wall, a bottom wall and side walls, the continuous process gap including an entrance opening for the workpiece to enter into the continuous process gap with the precursor material facing the top wall, an exit opening for the workpiece to exit from the continuous process gap and an exhaust opening located between the entrance and exit openings to remove gases from the continuous process gap; and
at least one roller having a rotational axis that is substantially transverse to the process direction and which has an outer roller surface disposed at least partially below the top wall of the continuous process gap to form a reduced gap between the outer roller surface of the roller and the bottom wall, wherein the reduced gap is smaller than the continuous process gap and wherein the at least one roller is configured such that the workpiece travels through the reduced gap with the precursor material facing the at least one roller as the workpiece is moved between the entrance opening and the exit opening in the process direction.

2. The reactor of claim 1, wherein the continuous process gap includes a workpiece high temperature processing section and a workpiece cooling section, wherein the workpiece high temperature processing section of the continuous process gap is located between the entrance opening and the exhaust opening and the workpiece cooling section is located between the exhaust opening and the exit opening.

3. The reactor of claim 2, wherein the vertical distance between the top wall and the bottom wall of the continuous process gap is in the range of 2-20 mm, and wherein the diameter of at least one roller is in the range of 1-19 mm.

4. The reactor of claim 3, wherein the at least one roller includes at least one first roller and at least one second roller.

5. The reactor of claim 4, wherein the diameter of the at least one first roller is in the range of 1-6 mm and the diameter of the at least one second roller is in the range of 1-19 mm.

6. The reactor of claim 4, wherein the at least one first roller includes a plurality of protection rollers each having a rotational axis that is substantially transverse to the process direction and each having a protection roller outer roller surface disposed at least partially below the top wall of the first section of the continuous process gap, wherein the protection roller outer roller surface of each of the protection rollers roll on the rotational axis upon contact with the precursor material, thereby preventing the precursor material from contacting the top wall when the continuous workpiece is moved through the workpiece high temperature processing section.

7. The reactor of claim 6, wherein the at least one second roller includes a gas isolation roller having a rotational axis that is substantially transverse to the process direction and having an isolation roller outer roller surface disposed at least partially below the top wall of the first section of the continuous process gap and adjacent the exhaust opening, wherein the gas isolation roller establishes a gas diffusion barrier against the transfer of gaseous species from the workpiece high temperature processing section into the workpiece cooling section and from workpiece cooling section into from the workpiece high temperature processing section when the continuous workpiece is moved through the workpiece high temperature processing section.

8. The reactor of claim 7 wherein the diameter of each of the plurality of protection rollers is less than the diameter of the at least one gas isolation roller.

9. The reactor of claim 8 wherein the top wall is substantially flat, with a plurality of cavities formed therein, each corresponding to the position of each of the plurality of protection rollers and the at least one gas isolation roller, such that each protection roller outer surface and each isolation roller outer surface fits partially within the corresponding cavity.

10. The reactor of claim 8, wherein the diameter of each of the plurality of protection rollers is in the range of 1-6 mm and the diameter of the at least gas isolation roller is in the range of 3-19 mm.

11. The reactor of claim 1, wherein the at least one roller is made of one of a roller body comprising a ceramic material and a roller body with a coating comprising the ceramic material.

12. The reactor of claim 11, wherein the ceramic material comprises at least one of quartz and graphite.

13. The reactor of claim 1, wherein the at least one roller is at least partially disposed within a cavity in the top wall of the continuous process gap.

14. The reactor of claim 1, wherein the length of the at least one roller is less than the width of the continuous process gap.

15. The reactor of claim 1, wherein the at least one roller is rotated by a motor at a speed such that the linear surface velocity of the at least one roller is substantially equal to the linear velocity of the continuous workpiece when the continuous workpiece is moved through the reduced gap.

16. The reactor of claim 1, wherein the at least one roller rotates on the rotational axis upon contact with the continuous workpiece as the continuous workpiece is moved through the reduced gap.

17. The reactor of claim 1, wherein the peripheral wall is made of stainless steel.
